(19) United States
(12) Patent Application Publication
(10) Pub. No.: US 2026/0018448 A1
(43) Pub. Date: Jan. 15, 2026

(54) BONDING APPARATUS AND BONDING METHOD

(71) Applicant: WUHAN XINXIN SEMICONDUCTOR MANUFACTURING CO., LTD., WUHAN (CN)

(72) Inventors: Chao TAO, WUHAN (CN); Junzhou LONG, WUHAN (CN); Li WANG, WUHAN (CN)

(73) Assignee: WUHAN XINXIN SEMICONDUCTOR MANUFACTURING CO., LTD., WUHAN (CN)

(21) Appl. No.: 19/333,057

(22) Filed: Sep. 18, 2025

Related U.S. Application Data
(63) Continuation of application No. PCT/CN2023/140752, filed on Dec. 21, 2023.

(30) Foreign Application Priority Data
Jul. 7, 2023 (CN) 202310839171.2

(51) Int. Cl. H01L 21/68; H01L 21/67; H01L 23/544

(52) U.S. Cl. CPC H01L 21/681; H01L 21/67121; H01L 23/544; H01L 2223/54426

(57) ABSTRACT

A bonding apparatus and a bonding method are provided. The bonding apparatus includes: a machine base, including a movable pick-up platform; and a grating assembly, configured to determine displacement information of the movable pick-up platform along a first direction and displacement information of the movable pick-up platform along a second direction. Based on the displacement information along the first direction and the displacement information along the second direction, the grating assembly is further configured to determine coordinate information of the movable pick-up platform.

### CROSS REFERENCE TO RELATED APPLICATIONS

The present application is a continuation-application of International (PCT) Patent Application No. PCT/CN2023/140752, filed Dec. 21, 2023, which claims foreign claims priority to Chinese Patent Application No. 202310839171.2, filed Jul. 7, 2023, both of which is incorporated herein in their entireties.

### TECHNICAL FIELD

The present disclosure relates to the field of semiconductor manufacturing technologies, and in particular to a bonding apparatus and a bonding method.

### BACKGROUND

As a semiconductor technology enters a post-Moore era, a structure of a chip is developing in a three-dimensional integration direction, so as to meet the requirement of high integration and high performance. A bonding technology is one of the important “More than Moore” technologies. A semiconductor bonding technology refers to a technology of directly combining two pieces of homogeneous or heterogeneous semiconductor materials after surface cleaning and activation treatment. Under a certain condition, wafers are bonded into one through van der Waals forces, molecular forces, or even atomic forces. Bonding accuracy is an important parameter of the bonding process and has a significant impact on the application of the bonding process.

### SUMMARY OF THE DISCLOSURE

According to a first aspect, some embodiments of the present disclosure provide a bonding apparatus. The bonding apparatus may include: a machine base, including a movable pick-up platform; and a grating assembly, configured to determine displacement information of the movable pick-up platform along a first direction and displacement information of the movable pick-up platform along a second direction; where based on the displacement information along the first direction and the displacement information along the second direction, the grating assembly is further configured to determine coordinate information of the movable pick-up platform.

According to a second aspect, some embodiments of the present disclosure provide a bonding method. The bonding method may include: reading a first alignment mark and a second alignment mark on a to-be-bonded first component; reading a third alignment mark and a fourth alignment mark on a to-be-bonded second component; determining a calibrated coordinate system based on the first alignment mark and the second alignment mark or based on the third alignment mark and the fourth alignment mark; determining a fixed coordinate in the calibrated coordinate system; determining first-direction coordinate information and second-direction coordinate information based on the first alignment mark, the second alignment mark, the third alignment mark, the fourth alignment mark, and the fixed coordinate; determining a bonding alignment position of the to-be-bonded first component and the to-be-bonded second component based on the first-direction coordinate information and the second-direction coordinate information; and bonding the to-be-bonded second component to a predetermined surface position of the to-be-bonded first component.

Specific embodiments and technical details are further described below with reference to the accompanying drawings. Other features, objectives, and advantages of the present disclosure will become apparent from the description, drawings, and claims.

### BRIEF DESCRIPTION OF THE DRAWINGS

In order to more clearly illustrate the technical solutions in the embodiments of the present disclosure, the following is a brief description of the drawings required for the description of the embodiments, and it will be obvious that the drawings in the following description are only some embodiments of the present disclosure, and that other drawings may be obtained from these drawings without creative work for those skilled in the art.

FIG. 1 is a schematic structural diagram of a bonding apparatus according to some embodiments of the present disclosure.

FIG. 2 is a schematic diagram of a process in which the bonding apparatus determines a first alignment mark and a second alignment mark on a first component according to some embodiments of the present disclosure.

FIG. 3 is a schematic diagram of a process in which the bonding apparatus identifies a reference mark according to some embodiments of the present disclosure.

FIG. 4 is a schematic diagram of a calibrated coordinate system defined by the bonding apparatus according to some embodiments the present disclosure.

FIG. 5 is a schematic diagram of a process in which the bonding apparatus determines a third alignment mark and a fourth alignment mark on a second component according to some embodiments of the present disclosure.

FIG. 6 is a schematic diagram of a process in which the bonding apparatus determines coordinate information along a first direction and coordinate information along a second direction according to some embodiments of the present disclosure.

FIG. 7 is a schematic diagram of a process in which the bonding apparatus corrects coordinate information of a relative position between the second component and the first component in the calibrated coordinate system according to some embodiments of the present disclosure.

FIG. 8 is a schematic diagram of a process in which the bonding apparatus bonds the second component to a predetermined surface position of the first component according to some embodiments of the present disclosure.

FIG. 9 is a schematic diagram of the coordinate information in the calibrated coordinate system when the second component is bonded to the predetermined surface position of the first component shown in FIG. 8.

FIG. 10 is a schematic flowchart of a bonding method according to some embodiments of the present disclosure.

FIG. 11 is a schematic structural diagram of a bonding apparatus according to some embodiments of the present disclosure.

FIG. 12 is a schematic structural diagram of a bonding apparatus according to some embodiments of the present disclosure.

FIG. 13 is a partial schematic structural diagram of a bonding apparatus according to some embodiments of the present disclosure.

FIG. 14 is a schematic structural diagram of a grating assembly according to some embodiments of the present disclosure.

### DETAILED DESCRIPTION

The technical solutions in embodiments of the present disclosure will be clearly and completely described below in conjunction with the accompanying drawings in the embodiments of the present disclosure, and it is obvious that the described embodiments are only a part of the embodiments of the present disclosure, but not all of them. Based on the embodiments in the present disclosure, all other embodiments obtained by those skilled in the art without creative labor fall within the scope of the present disclosure.

The terms “first”, “second”, and “third” in the present disclosure are intended for descriptive purposes only and are not to be construed as indicating or implying relative importance or implicitly indicating the number of indicated technical features. Therefore, a feature defined with “first”, “second”, or “third” may explicitly or implicitly include at least one such feature. In the description of the present disclosure, “a plurality of” or “multiple” means at least two, e.g., two, three, etc., unless otherwise expressly and specifically limited. All directional indications (e.g., up, down, left, right, forward, backward . . . ) in the present disclosure are intended only to explain the relative position relationship, movement, etc., between components in a particular posture (as shown in the accompanying drawings), and if that particular posture is changed, the directional indications are changed accordingly. In addition, the terms “include” and “have”, and any variations thereof are intended to cover non-exclusive inclusion. For example, a process, method, system, product, or apparatus including a series of steps or units is not limited to the listed steps or units, but In some embodiments further may include steps or units not listed, or In some embodiments further may include other steps or units inherent to the process, method, product, or apparatus.

References herein to “embodiment” mean that particular features, structures, or characteristics described in connection with an embodiment can be included in at least one embodiment of the present disclosure. The presence of the phrase at various positions in the specification does not necessarily mean the same embodiment, nor is it a separate or alternative embodiment that is mutually exclusive with other embodiments. It is understood, both explicitly and implicitly, by those skilled in the art that the embodiments described herein can be combined with other embodiments.

The present disclosure may be described in detail below in conjunction with the accompanying drawings and embodiments.

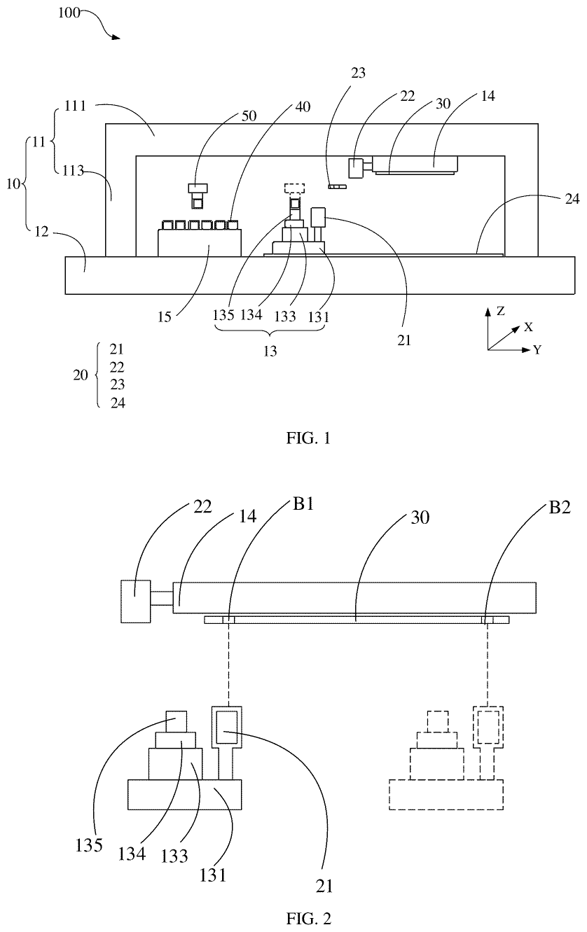

As shown in FIG. 1, FIG. 1 is a schematic structural diagram of a bonding apparatus according to some embodiments of the present disclosure. In some embodiments, as shown in FIG. 1, the bonding apparatus 100 may include a machine base 10 and a grating assembly 24. The machine base 10 may include a gantry 11, a base frame 12, a movable pick-up platform 13, and a first chuck 14. In some embodiments, the first chuck 14 is arranged on a side of the gantry 11 facing the base frame 12. The first chuck 14 is configured to carry a to-be-bonded first component 30. It should be noted that the first component 30 described as below may be referred to the to-be-bonded first component 30 before bonding, and for the sake of brevity, the to-be-bonded first component 30 may be described as the first component 30. The gantry 11 is disposed on the base frame 12. The grating assembly 24 is disposed at a side of the base frame 12 facing a top plate of the gantry 11. The movable pick-up platform 13 may be capable of freely moving within a plane where the base frame 12 is disposed, and may be configured to pick up a to-be-bonded second component 40 and move the picked second component 40 to a predetermined surface position of the to-be-bonded first component 30. It should be noted that the second component 40 described as below may be referred to the to-be-bonded second component 40 before bonding, and for the sake of brevity, the to-be-bonded second component 40 may be described as the second component 40. In some embodiments, the grating assembly 24 may be configured to determine displacement information of the movable pick-up platform 13 along a first direction Y and displacement information of the movable pick-up platform 13 along a second direction X. Based on the displacement information along the first direction Y and the displacement information along the second direction X, the grating assembly 24 may be further configured to determine coordinate information of the second component 40 along the first direction Y and coordinate information of the second component 40 along the second direction X.

In some embodiments, the bonding apparatus 100 may further include a reference assembly arranged on the machine base 10. The reference assembly may be configured to correct/adjust a relative position between the first component 30 and the second component 40 according to correction information. In some embodiments, the reference assembly may also be referred to as a correction assembly.

In some embodiments, the first component 30 may be held/located on a surface of the first chuck 14 facing the base frame 12. It may be understood that the first component 30 may be flipped by a manipulator and placed on the surface of the first chuck 14.

It may be understood that in some embodiments, the first component 30 may be a wafer or a chip. Correspondingly, the second component 40 may be the wafer or the chip.

In some embodiments, the gantry 11 may be approximately in a shape of a door frame. The gantry 11 may include a top plate 111 and two first side plates 113. The two first side plates 113 may be connected to the top plate 111, respectively. The two first side plates 113 are opposite to each other. A door-frame structure of the gantry 11 may be formed by the top plate 111 and the first two side plates 113. The base frame 12 may be substantially planar, and an end portion of each of the two side plates 113 of the gantry 11 is disposed on the base frame 12.

In some embodiments, the machine base 10 may further include a second chuck 15. The second chuck 15 is disposed at a side of the base frame 12 facing the top plate 111 of the gantry 11. The second chuck 15 may be configured to carry the second component 40.

In some embodiments, the machine base 10 may further include a base (not shown) arranged on a side of the bottom plate 121 away from the first side plate 113. The movable pick-up platform 13, the gantry 11, and the bottom plate 121 of the base frame 12 may be installed on the base. In some embodiments, the base may be made of marble. A vibration isolation and damping device may also be arranged at a bottom of the base, and may be configured to reduce the vibration caused by the movable pick-up platform 13 during a process of moving and bonding the second component 40 to the predetermined surface position of the first component 30, thereby improving the stability of the bonding apparatus 100.

In the bonding apparatus provided in the embodiments of the present disclosure, by arranging the gantry 11 on the base frame 12, the movable pick-up platform 13 may be capable of freely moving within a plane where the base frame 12 is disposed. In this way, it may be possible to improve the stability of the bonding apparatus to a certain extent, thereby further enhancing the motion accuracy of the movable pick-up platform 13.

Further as shown in FIGS. 1-2, in some embodiments, the movable pick-up platform 13 may be a macro-micro dual-stage motion mechanism. In some embodiments, the movable pick-up platform 13 may include a first driving member 131, a second driving member 133, a rotation driving member 134, and a bonding head 135, which may be sequentially stacked on a side of the base frame 12 facing the top plate 111 of the gantry 11. The bonding head 135 is connected to the rotation driving member 134, and an end of the bonding head 135 faces the top plate 111 of the gantry 11. The first driving member 131 may be configured to move the second driving member 133 and the rotation driving member 134 along the first direction Y and/or the second direction X in a horizontal plane, thereby moving the bonding head 135 along the first direction Y and/or the second direction X in the horizontal plane. In some embodiments, the second driving member 133 may be configured to move the rotation driving member 134 along a third direction Z in a plane approximately perpendicular to the horizontal plane, such that the bonding head 135 may be moved along the third direction Z. The rotation driving member 134 may be configured to rotate the bonding head 135, so as to enable the bonding head 135 to pick up the second component 40, and thus the second component 40 may be bonded to the predetermined surface position of the first component 30.

In some embodiments, the machine base 10 further includes a pickup head 50. The pickup head 50 may be capable of being driven to move freely in a range of the machine base 10, and may be configured to pick up the second component 40 from the second chuck 15 and transfer the picked second component 40 to the bonding head 135.

In some embodiments, the first driving member 131 may include a first macro-driving member and a first micro-driving member. The first macro-driving member may be disposed at a side of the base frame 12 facing the top plate 111 of the gantry 11. The first macro-driving member may be configured to coarsely move/coarsely adjust the second driving member 133 and the rotation driving member 134 along the first direction Y in the horizontal plane, such that the bonding head 135 may be moved along the first direction Y in the horizontal plane. The first micro-driving member may be disposed at the side of the base frame 12 facing the top plate 111 of the gantry 11. The first micro-driving member may be configured to finely move/finely adjust the second driving member 133 and the rotation driving member 134 along the first direction Y in the horizontal plane, such that the bonding head 135 may be finely moved along the first direction Y in the horizontal plane. The first macro-driving member may be configured to coarsely move the bonding head 135 along the first direction Y and perform coarse positioning with sub-micron accuracy. The first micro-driving member may finely move the bonding head 135 along the first direction Y and perform positioning with sub-micron accuracy through error compensation mechanisms. In this way, the first driving member 131 may implement the positioning with sub-micron accuracy of the bonding head 135 along the first direction Y through the coordinated actuation of the first macro-driving member and the first micro-driving member along the first direction Y.

In some embodiments, the first driving member 131 may include a second macro-driving member and a second micro-driving member. The second macro-driving member may be disposed at the side of the base frame 12 facing the top plate 111 of the gantry 11. The second macro-driving member may be configured to coarsely move the second driving member 133 and the rotation driving member 134 along the second direction X in the horizontal plane, such that the bonding head 135 may be moved along the second direction X in the horizontal plane. The second micro-driving member may be disposed at the side of the base frame 12 facing the top plate 111 of the gantry 11. The second micro-driving member may be configured to finely move the second driving member 133 and the rotation driving member 134 along the second direction X in the horizontal plane, such that the bonding head 135 may be finely moved along the second direction X in the horizontal plane. The second macro-driving member may coarsely move the bonding head 135 along the second direction X and perform coarse positioning with the sub-micron accuracy. The second micro-driving member may finely move the bonding head 135 along the second direction X and perform positioning with sub-micron accuracy through the error compensation mechanisms. In this way, the first driving member 131 may implement the positioning with sub-micron accuracy of the bonding head 135 along the second direction X through the coordinated actuation of the second macro-driving member and the second micro-driving member along the second direction X.

It may be understood that the first driving member 131 may include the first macro-driving member and the first micro-driving member as described in the foregoing embodiments, and/or the second macro-driving member and the second micro-driving member as described in the foregoing embodiments.

Accordingly, the second driving member 133 may move the rotation driving member 134 along the third direction Z, such that the second driving member 133 may implement accurate positioning of the bonding head 135 along the third direction Z. The rotation driving member 134 may implement positioning with micro-radian-level accuracy.

It should be noted that, each of the first driving member 131, the second driving member 133, and the rotation driving member 134 may further include a motor, such as a linear motor or a rotary motor. The motor may be configured to provide power to a corresponding driving member as described above. It may be understood that a structural design of the first macro-driving member or the first micro-driving member provided in the embodiments of the present disclosure may also be referred to a specific structure in the related art, as long as the structural design thereof may realize a function of moving the bonding head 135 along the first direction Y in the horizontal plane and implementing the positioning with sub-micron accuracy, which are not limited herein. Accordingly, a structural design of each of the second driving member 133, the second macro-driving member, the second micro-driving member, and the rotation driving member 134 may also be referred to a specific structure in the related art, as long as the structural design thereof may realize a corresponding function thereof.

In some embodiments, the first direction Y, the second direction X, and the third direction Z may be mutually perpendicular to each other. In some embodiments, the first direction Y may be approximately parallel to a Y-axis direction, the second direction X may be approximately parallel to an X-axis direction, and the third direction Z may be approximately parallel to a Z-axis direction. Correspondingly, the first macro-driving member and the first micro-driving member may also be referred to as a Y-axis macro-driving member and a Y-axis micro-driving member, respectively. The second macro-driving member and the second micro-driving member may also be referred to as an X-axis macro-driving member and an X-axis micro-driving member, respectively. The second driving member 133 may also be referred to as a Z-axis driving member.

In some embodiments, the movable pick-up platform 13 may also be a single-stage motion mechanism or other types of motion mechanisms, as long as the motion mechanism may be capable of moving the second component 40 to the predetermined surface position of the first component 30 and bonding the second component 40 to the predetermined surface position of the first component 30 in a case where the specific accuracy requirement may be met.

Further as shown in FIG. 1 and in combination with FIGS. 2-9, FIGS. 2-9 illustrate schematic diagrams of a working process of the bonding apparatus 100 according to some embodiments of the present disclosure. As shown in FIG. 1, the bonding apparatus 100 may further include a first image acquisition member 21 and a second image acquisition member 22.

In some embodiments, the first image acquisition member 21 may have a first viewing angle. The first image acquisition member 21 may be configured to read a first alignment mark B1 and a second alignment mark B2 on the first component 30. The first image acquisition member 21 may be disposed at a side of the first micro-driving member away from the second driving member 133, such that the first image acquisition member 21 may be capable of precisely moving with the first driving member 131. The first viewing angle may also be referred to as an upward viewing angle. It may be understood that a position at which the first image acquisition member 21 is disposed may not be limited to the side of the first micro-driving member away from the second driving member 133. In some embodiments, the first image acquisition member 21 may be disposed at any position of the first micro-driving member according to specific design requirements, as long as the first image acquisition member 21 may be capable of precisely moving with the first driving member 131 and may be capable of reading the first alignment mark B1 and the second alignment mark B2 on the first component 30.

As shown in FIG. 2, FIG. 2 is a schematic diagram of a process in which the bonding apparatus determines a first alignment mark and a second alignment mark on a first component according to some embodiments of the present disclosure. As shown in FIG. 2, during a process in which the movable pick-up platform 13 moves the second component 40 and bonds the second component 40 to the predetermined surface position of the first component 30, the first image acquisition member 21 may be capable of moving with the first driving member 131. In some embodiments, the first image acquisition member 21 may be capable of moving with the first driving member 131 to a position below the first chuck 14 carrying the first component 30, i.e., the position may correspond to a direction of the first chuck 14 facing the base frame 12. At this time, a field-of-view of the first image acquisition member 21 may be positioned below the first alignment mark B1 on the first component 30, such that the first image acquisition member 21 may read the first alignment mark B1 on the first component 30. The first image acquisition member 21 may be driven to continue to move until the field-of-view of the first image acquisition member 21 may be positioned below the second alignment mark B2 on the first component 30, such that the first image acquisition member 21 may read the second alignment mark B2 on the first component 30. That is, when the field-of-view of the first image acquisition member 21 is positioned within an area where the first component 30 is located, the first image acquisition member 21 may be capable of reading the first alignment mark B1 and the second alignment mark B2 on the first component 30.

The second image acquisition member 22 may have a second viewing angle, and may be capable of reading a third alignment mark T1 and a fourth alignment mark T2 on the second component 40. In some embodiments, the second image acquisition member 22 may be disposed at a side of the first chunk 14. For example, the second image acquisition member 22 may be fixedly disposed at a side surface of the first chunk 14, the movable pick-up platform 13 may be controlled to move the bonding head 135, such that the picked-up second component 40 may be moved to a position below the second image acquisition member 22 until the second image acquisition member 22 be capable of reading the third alignment mark T1 and the fourth alignment mark T2 on the second component 40. In some embodiments, the second viewing angle may also be referred to as a downward viewing angle. That is, in a case where the second component 40 picked up by the movable pick-up platform 13 is moved to the field-of-view of the second image acquisition member 22, the second image acquisition member 22 may be configured to read the third alignment mark T1 and the fourth alignment mark T2 on the second component 40.

In some embodiments, each of the first image acquisition member 21 and the second image acquisition member 22 may be a camera. In some embodiments, the first image acquisition member 21 may also be referred to as an upward-looking camera. The second image acquisition member 22 may also be referred to as a downward-looking camera.

In some embodiments, the reference assembly may include a reference member 23. The reference member 23 may be disposed on the machine base 10. The reference member 23 may be driven to move freely between the top plate 111 of the gantry 11 and the second image acquisition member 22. For example, the reference member 23 may be driven to move freely between the bonding head 135 and the second image acquisition member 22. Alternatively, the reference member 23 may be driven to move freely between the first image acquisition member 21 and the second image acquisition member 22. A free movement range of the reference member 23 is not less than an intersection of a maximum field-of-view of the first image acquisition member 21 and a maximum field-of-view of the second image acquisition member 22. In some embodiments, the reference member 23 may be driven to move freely between the top plate 111 of the gantry 11 and the second image acquisition member 22 by means of a cylinder or a motor. In some embodiments, the reference member 23 may include a transparent component, a translucent component, or a structural component with a through-hole. A reference mark 231 may be arranged on the reference member 23. Of course, the reference member 23 may also be other structural designs, as long as the structural design may enable the first image acquisition member 21 to recognize the reference mark on the second image acquisition member 22 through the reference member 23, or may enable the second image acquisition member 22 to recognize the reference mark on the first image acquisition member 21 through the reference member 23.

It may be understood that the reference member 23 may be a calibration piece. Accordingly, the reference mark 231 may also be a calibration mark disposed on the calibration piece.

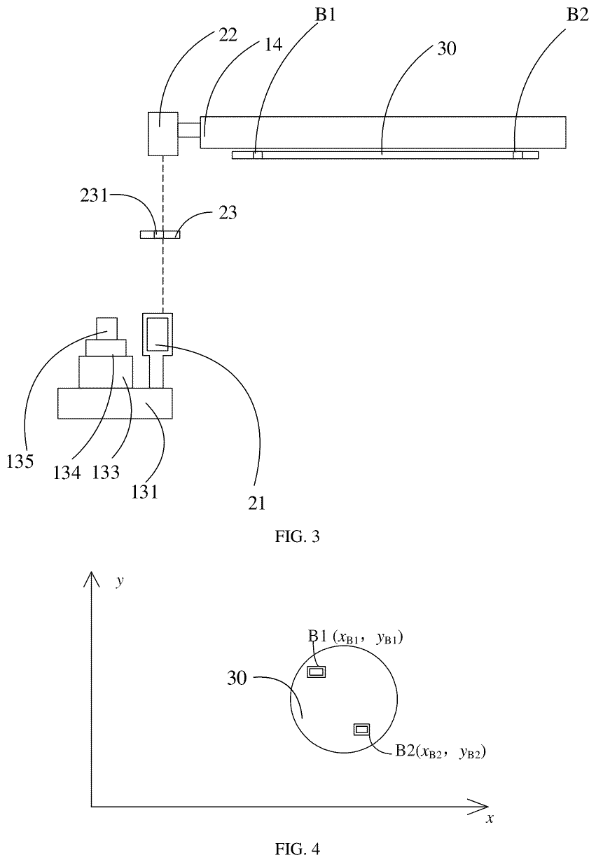

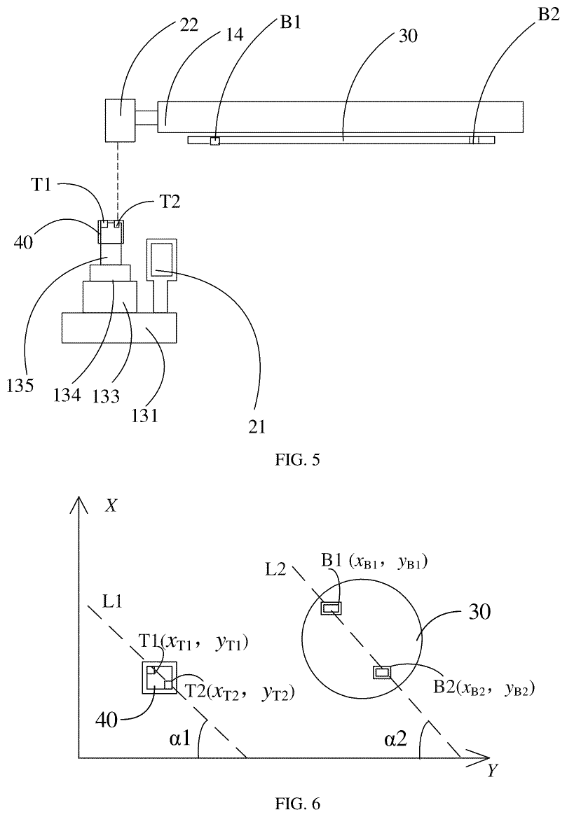

As shown in FIGS. 3-5, FIG. 3 is a schematic diagram of a process in which the bonding apparatus identifies a correction mark according to some embodiments of the present disclosure. FIG. 4 is a schematic diagram of a calibrated coordinate system defined by the bonding apparatus according to some embodiments the present disclosure. FIG. 5 is a schematic diagram of a process in which the bonding apparatus determines a third alignment mark and a fourth alignment mark on a second component according to some embodiments of the present disclosure.

In some embodiments, based on the read first alignment mark B1 and the read second alignment mark B2, the second image acquisition member 22 may cooperate with the reference member 23 and the first image acquisition member 21 to define a calibrated coordinate system/correction coordinate system. In some embodiments, the first image acquisition member 21 may be driven to move with the first driving member 131. For example, the first image acquisition member 21 may be driven to move to a position above the second image acquisition member 22 until a connecting line between a center point of the first image acquisition member 21 and a center point of the second image acquisition member 22 is approximately perpendicular to a plane at which the first chuck 14 is located, i.e., the center point of the first image acquisition member 21 and the center point of the second image acquisition member 22 may be aligned with each other in a direction approximately parallel to the third direction Z. In some embodiments, the reference member 23 is moved to the position above the second image acquisition member 22, and is moved to be located between the first image acquisition member 21 and the second image acquisition member 22. At this time, a connecting line between the center point of the first image acquisition member 21, a center point of the reference member 23, and the center point of the second image acquisition member 22 may be approximately perpendicular to the plane at which the base frame 12 is located. In this way, the reference mark 231 may be simultaneously recognized by the first image acquisition member 21 and the second image acquisition member 22, such that it may be possible to determine the fixed coordinate in the calibrated coordinate system. That is, the first image acquisition member 21 and the reference member 23 may be moved to the position above the second image acquisition member 22, and the center point of the first image acquisition member 21, the center point of the reference member 23, and the center point of the second image acquisition member 22 may be aligned with each other in the direction approximately parallel to the third direction Z at the same time. The first image acquisition member 21 and the second image acquisition member 22 may be configured to simultaneously recognize the reference mark 231, such that it may be possible to determine the fixed coordinate in the calibrated coordinate system. In some embodiments, the fixed coordinate may be an origin coordinate in the calibrated coordinate system.

It may be understood that, the center point of the first image acquisition member 21 may be a center of the field-of-view of the first image acquisition member 21. Accordingly, the center point of the second image acquisition member 22 may be a center of the field-of-view of the second image acquisition member 22.

In some embodiments, since position information corresponding to the first alignment mark B1 and the second alignment mark B2 on the first component 30 read by the first image acquisition member 21 and position information corresponding to the third alignment mark T1 and the fourth alignment mark T2 on the second component 40 read by the second image acquisition member 22 respectively correspond to different coordinate systems, in a structural design of the bonding apparatus provided in the embodiments of the present disclosure, by arranging the reference member 23 and enabling the first image acquisition member 21 and the second image acquisition member 22 to simultaneously recognize the reference mark 231, the field-of-view of the first image acquisition member 21 and the field-of-view of the second image acquisition member 22 may be aligned with a same object, i.e., the reference mark 231 on the reference member 23. At this time, it should be considered that the first image acquisition member 21 and the second image acquisition member 22 may be aligned with each other. Therefore, the position information of the second image acquisition member 22 may be first determined by the first image acquisition member 21, the first image acquisition member 21 and the second image acquisition member 22 may simultaneously recognize the reference mark 231, and the position information corresponding to the reference mark 231 read by the first image acquisition member 21 and the second image acquisition member 22 may be converted into a same coordinate system, i.e., the calibrated coordinate system, such that it may be possible to determine the fixed coordinate in the calibrated coordinate system.

In other embodiments, the reference member 23 may not be provided, and the reference mark 231 may be disposed on a certain member of the bonding apparatus. That is, the reference mark 231 may also be disposed on the certain member of the bonding apparatus. For example, the reference mark 231 may be disposed on the second image acquisition member 22, and the reference mark 231 may be read by the first image acquisition member 21, such that it may also be possible to determine the fixed coordinate in the calibrated coordinate system.

In some embodiments, the second image acquisition member 22 may be further configured to read the third alignment mark T1 and the fourth alignment mark T2 on the second component 40 picked up by the bonding head 135 according to the calibrated coordinate system. In some embodiments, as shown in FIG. 5, after the fixed coordinate in the calibrated coordinate system is determined, the reference member 23 may be moved away, for example, the reference member 23 may be moved out of the maximum field-of-view of the first image acquisition member 21 or the maximum field-of-view of the second image acquisition member 22. The pickup head 50 may be controlled to move a position above the second chuck 15, i.e., the position may correspond to a direction of the second chuck 15 facing the top plate 111 of the gantry 11. In addition, the pickup head 50 may be controlled to pick up the second component 40 from the second chuck 15, and place the picked-up second component 40 onto the bonding head 135. Further, the movable pick-up platform 13 may be controlled to drive the bonding head 135 to move until the picked second component 40 is moved to the position below the second image acquisition member 22, i.e., the position may correspond to a direction of the second image acquisition member 22 facing the base frame 12. In this case, the field-of-view of the second image acquisition member 22 is positioned below the third alignment mark T1 and the fourth alignment mark T2 on the second component 40, such that the second image acquisition member 22 may read the third alignment mark T1 and the fourth alignment mark T2 on the second component 40. In this way, the third alignment mark T1 and the fourth alignment mark T2 on the second component 40 picked up by the bonding head 135 may be read by the second image acquisition member 22.

It may be understood that the reference member 23 may also be disposed at other positions in the bonding apparatus 100, as long as the following condition may be met. That is, when it is necessary to determine the fixed coordinate in the calibrated coordinate system, the reference member 23 may be moved between the first image acquisition member 21, and the center point of the first image acquisition member 21, the center point of the reference member 23, and the center point of the second image acquisition member 22 may be aligned with each other in the direction approximately parallel to the third direction Z at the same time. After the fixed coordinate is determined, the reference member 23 may be moved away, for example, the reference member 23 may be moved out of the maximum field-of-view of the first image acquisition member 21 or the maximum field-of-view of the second image acquisition member 22.

In some embodiments, the reference member 23 may have an appropriate thickness and a thermal expansion coefficient, such that it may be possible to reduce a difference between an optical path of the first image acquisition member 21 reaching the reference member 23 and an optical path of the second image acquisition member 22 reaching the reference member 23.

In some embodiments, the calibrated coordinate system may also be referred to as a bonding coordinate system, and may include an X-axis and a Y-axis.

In other embodiments, the fixed coordinate in the calibrated coordinate system may also be determined by the first image acquisition member 21 and the second image acquisition member 22. In some embodiments, the second image acquisition member 22 may be fixedly disposed at the side surface of the first chunk 14, and thus a position at which the second image acquisition member 22 is disposed is fixed. Based on the read first alignment mark B1 and the read second alignment mark B2, the calibrated coordinate system may be defined. In some embodiments, the first image acquisition member 21 may be driven to move with the first driving member 131. For example, the first image acquisition member 21 may be driven to move to the position below the second image acquisition member 22 until a connecting line between a center point of the first image acquisition member 21 and a center point of the second image acquisition member 22 is approximately perpendicular to a plane at which the first chuck 14 is located, i.e., the center point of the first image acquisition member 21 and the center point of the second image acquisition member 22 may be aligned with each other in a direction approximately parallel to the third direction Z, such that it may be possible to determine the fixed coordinate in the calibrated coordinate system.

Further as shown in FIG. 1 and in combination with FIGS. 6-9, in some embodiments, the grating assembly 24 is disposed at the side of the base frame 12 facing the top plate of the gantry 11, and based on a coordinate relationship/positional relationship of the first alignment mark B1, the second alignment mark B2, the third alignment mark T1, and the fourth alignment mark T2 in the calibrated coordinate system, the grating assembly 24 may be configured to determine an angular deviation between the first component 30 and the second component 40 in the calibrated coordinate system. In some embodiments, the grating assembly 24 may further cooperate with the first driving member 131, the second driving member 133, and the rotation driving member 134 to adjust a position of the second component 40 through the bonding head 135.

In some embodiments, as shown in FIG. 6, FIG. 6 is a schematic diagram of a process in which the bonding apparatus determines coordinate information along a first direction and coordinate information along a second direction according to some embodiments of the present disclosure. In the calibrated coordinate system, a first connecting line between the third alignment mark T1 and the fourth alignment mark T2 on the second component 40 may be assumed to be L1. A first angle between the L1 and the X-axis direction in the calibrated coordinate system may be assumed to be α1. A second connecting line between the first alignment mark B1 and the second alignment mark B2 on the first component 30 may be assumed to be L2. A second angle between the L2 and the X-axis direction in the calibrated coordinate system may be assumed to be α2. An angular deviation Δα between the first component 30 and the second component 40 in the calibrated coordinate system is an absolute value of a difference between the first angle α1 and the second angle α2, i.e., Δα=|α2−α1|.

In some embodiments, as shown in FIG. 1, the grating assembly 24 may be a planar grating, and a positioning accuracy thereof may achieve a nanometer-level. It may be understood that a specific structure and a working principle of the grating assembly 24 may also refer to the related technology, which is not limited herein, as long as the grating assembly 24 may implement the following function. That is, the grating assembly 24 may be capable of measuring of a displacement change of the movable pick-up platform 13 along the first direction and a displacement change of the movable pick-up platform 13 along the second direction and determining the displacement information of the movable pick-up platform 13 along the first direction and the displacement information of the movable pick-up platform 13 along the second direction, respectively, so as to achieve precise positioning of the movable pick-up platform 13. Further, the grating assembly 24 may be capable of determining an angular deviation between the first component 30 and the second component 40 in the calibrated coordinate system based on coordinate relationship of the first alignment mark B1, the second alignment mark B2, the third alignment mark T1, and the fourth alignment mark T2 in the calibrated coordinate system. In addition, the grating assembly 24 may be capable of cooperating with the first driving member, the second driving member, and the rotation driving member to adjust the position of the second component 40 through the bonding head 135 to determine a bonding alignment position of the first component 30 and the second component 40.

In some embodiments, the grating assembly 24 may be disposed on the base frame 12 and configured to measure a displacement change of the movable pick-up platform 13 along the first direction Y and a displacement change of the movable pick-up platform 13 along the second direction X, such that the displacement information of the movable pick-up platform 13 along the first direction Y and the displacement information of the movable pick-up platform 13 along the second direction X may be determined, respectively.

In some embodiments, the grating assembly 24 may include a first grating unit 241 and a second grating unit 242. The first grating unit 241 includes a first grating scale 2411 and a first telescoping member 2412. The first grating scale 2411 is disposed on the machine base 10, such as the base frame 12 of the machine base 10, and is parallel to the first direction Y. One end of the first telescoping member 2412 is connected to the first grating scale 2411, and the other end of the first telescoping member 2412 is connected to the movable pick-up platform 13. The first telescoping member 2412 may be configured to synchronously move with the movable pick-up platform 13 along the first direction Y and telescopically retract/move with the movable pick-up platform 13 along the second direction X. The second grating unit 242 includes a second grating scale 2421 and a second telescoping member 2422. The second grating scale 2421 is disposed on the machine base 10, such as the base frame 12 of the machine base 10, and is parallel to the second direction X. One end of the second telescoping member 2422 is connected to the first grating scale 2411, and the other end of the second telescoping member 2422 is connected to the movable pick-up platform 13. The second telescoping member 2422 may be configured to synchronously move with the movable pick-up platform 13 along the second direction X and telescopically retract/move with the movable pick-up platform 13 along the first direction Y.

In some embodiments, the first grating unit 241 may further include a first sensor 2413 located on the first grating scale 2411. The first sensor 2413 is connected to the first telescoping member 2412 and configured to measure a displacement generated along the first direction Y. The second grating unit 242 may further include a second sensor 2423 located on the second grating scale 2421. The second sensor 2423 is connected to the second telescoping member 2422 and configured to measure a displacement generated along the second direction X.

In other embodiments, the grating assembly 24 may not include the first telescoping member 2412 and the second telescoping member 2422, i.e., the grating assembly 24 may include the first grating unit 241 and the second grating unit 242. The first grating unit 241 is disposed on the machine base 10, such as the base frame 12 of the machine base 10, and is parallel to the first direction Y. The second grating unit 242 is disposed on the machine base 10, such as the base frame 12 of the machine base 10, and is parallel to the second direction X. In some embodiments, the first grating scale 2411 may be configured to synchronously move with the movable pick-up platform 13 along the first direction Y, and/or the second grating scale 2421 may be configured to synchronously move with the movable pick-up platform 13 along the second direction X. That is, at least one grating scale may be capable of synchronously moving with the movable pick-up platform 13. Correspondingly, the first grating unit 241 may further include the first sensor 2413 disposed on the first grating scale 2411. The first sensor 2413 may also be capable of synchronously moving with the movable pick-up platform 13 along the first direction Y and measuring the displacement generated along the first direction Y. Similarly, the second grating unit 242 may further include the second sensor 2423 disposed on the second grating scale 2421. The second sensor 2423 may also be capable of synchronously moving with the movable pick-up platform 13 along the second direction X and measuring the displacement generated along the second direction X.

In some embodiments, the grating assembly 24 may further include a system connection line configured to connect to a computer system 243. Based on the determined coordinate relationship along the first direction Y and the second direction X, the computer system 243 may be configured to generate first-direction coordinate information (i.e., the coordinate information along the first direction Y) related to the coordinate relationship of the first alignment mark B1, the second alignment mark B2, the third alignment mark T1, and the fourth alignment mark T2 along the first direction Y, and generate second-direction coordinate information (i.e., the coordinate information along the second direction X) related to the coordinate relationship of the first alignment mark B1, the second alignment mark B2, the third alignment mark T1, and the fourth alignment mark T2 along the second direction X. In some embodiments, based on the first-direction coordinate information and the second-direction coordinate information, the computer system 243 may further be configured to determine the angular deviation between the first component 30 and the second component 40 in the calibrated coordinate system. That is, the coordinate relationship of the first alignment mark B1, the second alignment mark B2, the third alignment mark T1, and the fourth alignment mark T2 along the first direction Y and the second direction X may be determined by the grating assembly 24.

In some embodiments, the grating assembly 24 may further include a reader disposed on the base frame 12, such as a planar grating reader. The reader may be configured to record the displacement and the displacement change of the first driving member 131 along the first direction Y measured by the first sensor 2413 and/or the displacement and the displacement change of the first driving member 131 along the second direction X measured by the second sensor 2423. In addition, the reader may further be configured to transmit the recorded result to the computer system 243. In other embodiments, the reader may be omitted, and displacement information measured by the first grating unit 241 and displacement information measured by the second grating unit 242 may be directly transmitted to the computer system 243.

In some embodiments, the system connection line of the grating assembly 24 and the computer system 243 may cooperate to generate the first-direction coordinate information related to coordinate relationship of the first alignment mark B1, the second alignment mark B2, the third alignment mark T1, and the fourth alignment mark T2 along the first direction Y, and the second-direction coordinate information related to the coordinate relationship of the first alignment mark B1, the second alignment mark B2, the third alignment mark T1, and the fourth alignment mark T2 along the second direction X. That is, the correction information may be obtained. In some embodiments, the correction information may include the first-direction coordinate information, the second-direction coordinate information, and the angular deviation.

In some embodiments, when the first micro-driving member finely moves the second driving member 133 and the rotation driving member 134 in the horizontal plane along the first direction Y, resulting in a displacement change along the first direction Y, i.e., which may enable the second driving member 133 and the rotation driving member 134 undergo the displacement change along the first direction Y, the first grating unit 241 of the grating assembly 24 may be capable of measuring the displacement change of the second driving member 133 and the rotation driving member 134 along the first direction Y due to a case that the movable pick-up platform 13 may be capable of freely moving within the plane where the base frame 12 is disposed and the grating assembly 24 is disposed on the base frame 12. In some embodiments, the computer system 243 may be configured to convert the displacement change along the first direction Y into the coordinate information along the first direction Y, so as to generate the first-direction coordinate information related to the coordinate relationship of the first alignment mark B1, the second alignment mark B2, the third alignment mark T1, and the fourth alignment mark T2 along the first direction Y. That is, when the displacement of the first driving member 131 of the movable pick-up platform 13 along the first direction Y may be measured by the first grating unit 241 of the grating assembly 24, the coordinate relationship of the first alignment mark B1, the second alignment mark B2, the third alignment mark T1, and the fourth alignment mark T2 along the first direction Y may be determined. In addition, the system connection line of the grating assembly 24 and the computer system 243 may cooperate to generate the first-direction coordinate information related to coordinate relationship of the first alignment mark B1, the second alignment mark B2, the third alignment mark T1, and the fourth alignment mark T2 along the first direction Y.

In some embodiments, as shown in FIG. 6, the first-direction coordinate information related to the coordinate relationship of the first alignment mark B1, the second alignment mark B2, the third alignment mark T1, and the fourth alignment mark T2 along the first direction Y may be expressed in the following manner. That is, in the calibrated coordinate system, the first alignment mark B1, the second alignment mark B2, the third alignment mark T1, and the fourth alignment mark T2 may be assumed to be ordinate values on the Y-axis, respectively. For example, the first alignment mark B1, the second alignment mark B2, the third alignment mark T1, and the fourth alignment mark T2 may be respectively marked as B1 ( . . . , y_{B1}), B2 ( . . . , y_{B2}), T1 ( . . . , y_{T1}), and T2 ( . . . , y_{T2}), which may be the coordinate information along the first direction Y.

In some embodiments, when the second micro-driving member finely moves the second driving member 133 and the rotation driving member 134 in the horizontal plane along the second direction X, resulting in a displacement change along the second direction X, i.e., which may enable the second driving member 133 and the rotation driving member 134 undergo the displacement change along the second direction X, the first grating unit 241 of the grating assembly 24 may be capable of measuring the displacement change of the second driving member 133 and the rotation driving member 134 along the second direction X due to a case that the movable pick-up platform 13 may be capable of freely moving within the plane where the base frame 12 is disposed and the grating assembly 24 is disposed on the base frame 12. In some embodiments, the computer system 243 may be configured to convert the displacement change along the second direction X into the coordinate information along the second direction X, so as to generate the second-direction coordinate information related to the coordinate relationship of the first alignment mark B1, the second alignment mark B2, the third alignment mark T1, and the fourth alignment mark T2 along the second direction X. That is, when the displacement of the first driving member 131 of the movable pick-up platform 13 along the second direction X may be measured by the second grating unit 242 of the grating assembly 24, the coordinate relationship of the first alignment mark B1, the second alignment mark B2, the third alignment mark T1, and the fourth alignment mark T2 along the second direction X may be determined. In addition, the system connection line of the grating assembly 24 and the computer system 243 may cooperate to generate the second-direction coordinate information related to coordinate relationship of the first alignment mark B1, the second alignment mark B2, the third alignment mark T1, and the fourth alignment mark T2 along the second direction X.

In some embodiments, as shown in FIG. 6, the second-direction coordinate information related to the coordinate relationship of the first alignment mark B1, the second alignment mark B2, the third alignment mark T1, and the fourth alignment mark T2 along the second direction X may be expressed in the following manner. That is, in the calibrated coordinate system, the first alignment mark B1, the second alignment mark B2, the third alignment mark T1, and the fourth alignment mark T2 may be assumed to be abscissa values on the X-axis, respectively. For example, the first alignment mark B1, the second alignment mark B2, the third alignment mark T1, and the fourth alignment mark T2 may be respectively marked as B1 (x_{B1}, . . . ), B2 (x_{B2}, . . . ), T1 (x_{T1}, . . . ), and T2 (x_{T2}, . . . ), which may be the coordinate information along the second direction X.

In this way, after the fixed coordinate in the calibrated coordinate system is determined, the first grating unit 241 and the second grating unit 242 of the grating assembly 24, and the computer system 243 may cooperate to determine the coordinate information of the first alignment mark B1, the second alignment mark B2, the third alignment mark T1, and the fourth alignment mark T2 along the first direction Y and the coordinate information of the first alignment mark B1, the second alignment mark B2, the third alignment mark T1, and the fourth alignment mark T2 along the second direction X, which may be respectively marked as B1 (x_{B1}, y_{B1}), B2 (x_{B2}, y_{B2}), T1 (x_{T1}, y_{T1}), and T2 (x_{T2}, y_{T2}). Based on this, the first angle α1 may be determined through the coordinate information of B1 (x_{B1}, y_{B1}) and B2 (x_{B2}, y_{B2}), and the second angle α2 may be determined through the coordinate information of T1 (x_{T1}, y_{T1}), and T2 (x_{T2}, y_{T2}), thereby determining the angular deviation Δα between the first component 30 and the second component 40 in the calibrated coordinate system.

In some embodiments, based on the first-direction coordinate information and the second-direction coordinate information, such as B1 (x_{B1}, y_{B1}), B2 (x_{B2}, y_{B2}), T1 (x_{T1}, y_{T1}), and T2 (x_{T2}, y_{T2}), the computer system 243 may be configured to determine that the angular deviation Δα between the first component 30 and the second component 40 in the calibrated coordinate system is the difference between the first angle α1 and the second angle α2. In this way, the correction information, such as B1 (x_{B1}, y_{B1}), B2 (x_{B2}, y_{B2}), T1 (x_{T1}, y_{T1}), T2 (x_{T2}, y_{T2}), and Δα, may be obtained.

Therefore, in the structural design of the bonding apparatus provided by the embodiments of the present disclosure, based on the read first and second alignment marks or the read third and fourth alignment marks, the calibrated coordinate system may be defined by the computer system 243. In some embodiments, the reference mark may be disposed on the reference member or the other elements of the bonding apparatus, and when the reference assembly is disposed at a same position, the different coordinate information may be obtained by the first image acquisition member and the second image acquisition member, such that it may be possible to determine the fixed coordinate in the calibrated coordinate system.

In the bonding apparatus provided by the embodiments of the present disclosure, by connecting the computer system 243 of the grating assembly to the first grating unit 241 and the second grating unit 242, and based on the determined fixed coordinate, the computer system 243 may be capable of generating the coordinate information of the first alignment mark, the second alignment mark, the third alignment mark, and the fourth alignment mark along the first direction and the coordinate information of the first alignment mark, the second alignment mark, the third alignment mark, and the fourth alignment mark along the second direction in the calibrated coordinate system. That is, by controlling the computer system 243, the displacement information along the first direction Y determined by the first grating unit 241 may be converted into the first-direction coordinate information in the calibrated coordinate system, such as B1 ( . . . , y_{B1}), B2 ( . . . , y_{B2}), T1 ( . . . , y_{T1}), and T2 ( . . . , y_{T2}). Similarly, by controlling the computer system 243, the displacement information along the second direction X determined by the second grating unit 242 may be converted into the second-direction coordinate information in the calibrated coordinate system, such as B1 (x_{B1}, . . . ), B2 (x_{B2}, . . . ), T1 (x_{T1}, . . . ), and T2 (x_{T2}, . . . ).

In some embodiments, based on the generated first-direction coordinate information and the generated second-direction coordinate information, the computer system 243 may further be capable of determining the angular deviation between the predetermined surface position of the first component and the position of the second component. The grating assembly may cooperate with the movable pick-up platform to adjust the position of the second component, such that it may be possible to determine a bonding alignment position of the first component and the second component, and thus the second component may be bonded to the predetermined surface position of the first component.

In some embodiments, when the angular deviation Δα is greater than a predetermined threshold, the grating assembly 24 may cooperate with the first macro-driving/micro-driving member, the second macro-driving/micro-driving member, the second driving member 133, and the rotation driving member 134 to implement the positioning with sub-micron accuracy along the first direction Y, the second direction X, and the third direction Z and implement positioning with micro-radian-level accuracy for the bonding head 135. In this way, the movable pick-up platform 13 may form a high-precision movement platform, such that the bonding head 135 may be driven to adjust the position of the second component 40 until the angular deviation Δα is less than or equal to the predetermined threshold. An angular deviation of the predetermined threshold may be 0°, 0.5°, or 1°. A specific value of the angular deviation of the predetermined threshold may be set according to specific design requirements, which is not limited herein. In some embodiments, the angular deviation of the predetermined threshold Δα=0°, i.e., α1′=α2. α1′ represents a third angle between a third connecting line L1′ and the X-axis direction in the calibrated coordinate system after the position of the second component 40 is adjusted, where the third connecting line L1′ is a connecting line between the third alignment mark T1 and the fourth alignment mark T2.

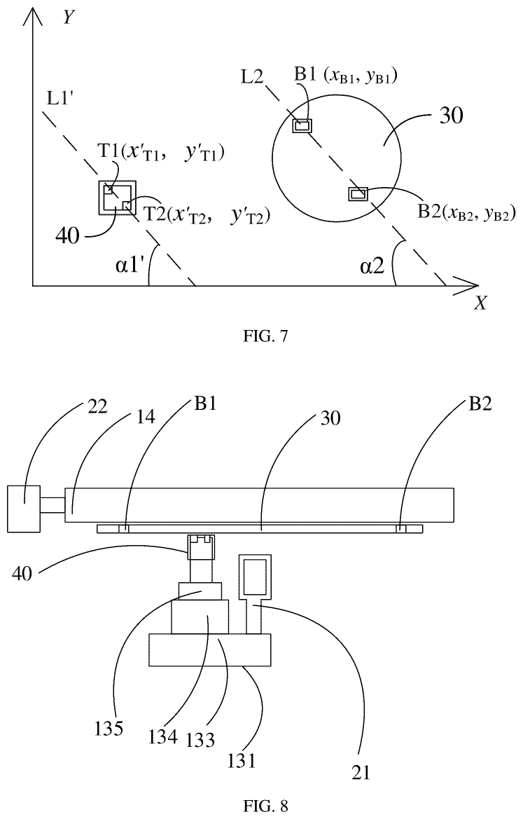

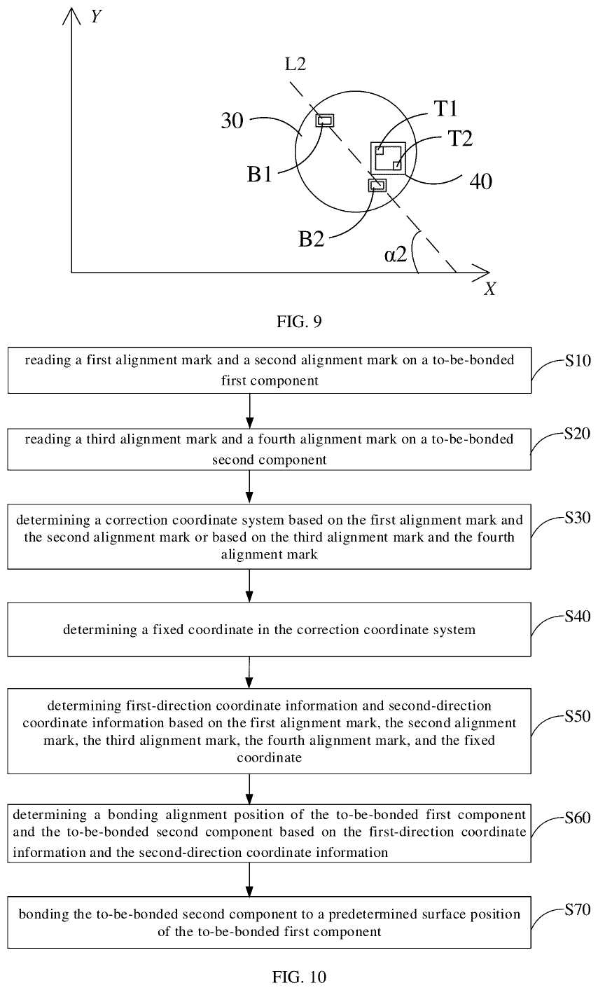

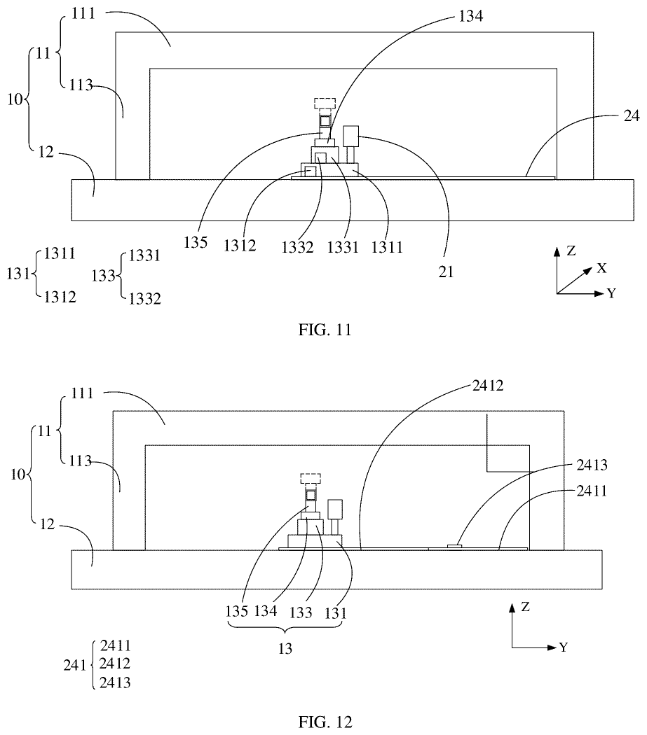

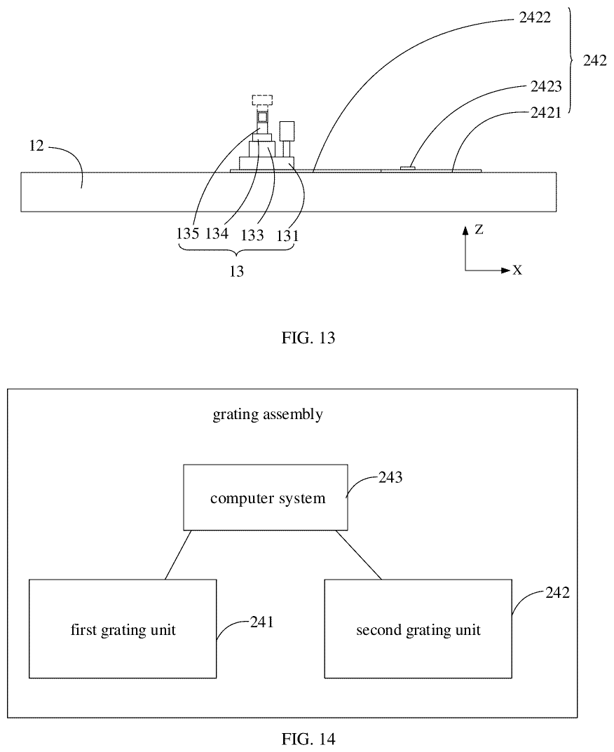

In some embodiments, as shown in FIGS. 7-9, FIG. 7 is a schematic diagram of a process in which the bonding apparatus corrects coordinate information of a relative position between the second component and the first component in the calibrated coordinate system according to some embodiments of the present disclosure. FIG. 8 is a schematic diagram of a process in which the bonding apparatus bonds the second component to a predetermined surface position of the first component according to some embodiments of the present disclosure. FIG. 9 is a schematic diagram of the coordinate information in the calibrated coordinate system when the second component is bonded to the predetermined surface position of the first component as shown in FIG. 8.

In some embodiments, as shown in FIG. 7, in the calibrated coordinate system, the coordinate information of the position of the second component 40 after being adjusted by the bonding head 135 may be described as follows. The coordinate information corresponding to the coordinate relationship of the third alignment mark T1 and the fourth alignment mark T2 along the first direction Y and the coordinate relationship of the third alignment mark T1 and the fourth alignment mark T2 along the second direction X may be described that in the calibrated coordinate system, a position of the third alignment mark T1 may be adjusted to (x′_{T1}, y′_{T1}), and a position of the third alignment mark T2 may be adjusted to T2 (x′_{T1}, y′_{T2}). Thus, α1′ may be calculated through the adjusted coordinate information T1 (x′_{T1}, y′_{T1}) and T2 (x′_{T2}, y′_{T2}). In some embodiments, when α1′ is adjusted to meet the condition that the angular deviation Δα=0, i.e., α1′=α2, which indicates that the relative position between the first component 30 and the second component 40 reaches the predetermined threshold. At the same time, the coordinate information of the third alignment mark T1 and the fourth alignment mark T2 in the calibrated coordinate system may be illustrated in FIG. 9. In some embodiments, the second driving member of the movable pick-up platform may move the second component to the predetermined surface position of the first component, and the second component may be bonded to the predetermined surface position of the first component, as shown in FIG. 8.

In some embodiments, α1′ may be obtained in the following manner. The coordinate relationship of the third alignment mark T1 and the fourth alignment mark T2 along the first direction Y and the coordinate relationship of the third alignment mark T1 and the fourth alignment mark T2 along the second direction may be obtained by the first grating unit 241 and the second grating unit 242 of the grating assembly 24. The computer system 243 may calculate the angular deviation Δα and the coordinate information of the third alignment mark T1 and the fourth alignment mark T2 along the first direction Y and the coordinate information of the third alignment mark T1 and the fourth alignment mark T2 along the second direction X, i.e., T1 (x′d, y′_{T1}) and T2 (x′_{T2}, y′_{T2}). Displacement differences between T1 (x′_{T1}, y′_{T1}) and T2 (x′_{T2}, y′_{T2}) and T1 (x_{T1}, y_{T1}) and T2 (x_{T2}, y_{T2}) may also be referred to as axial displacement differences, i.e., Δx and Δy. In some embodiments, α1′ may be compensated through a visual closed-loop, and the axial displacement differences Δx and Δy may be compensated through the grating assembly 24 in a closed-loop manner, respectively.

In the structural design of the bonding apparatus provided by the embodiments of the present disclosure, by arranging the grating assembly, the displacement change of the movable pick-up platform along the first direction and the displacement change of the movable pick-up platform along the second direction may be measured, such that the displacement information of the movable pick-up platform along the first direction and the displacement information of the movable pick-up platform along the second direction may be determined. In addition, based on the displacement information of the movable pick-up platform along the first direction and the displacement information of the movable pick-up platform along the second direction, the coordinate information of the second component along the first direction and the coordinate information of the second component along the second direction may further be determined by the grating assembly. In this way, a high-precision motion closed-loop may be formed by the grating assembly and the movable pick-up platform, such that it may be possible to implement precise positioning of the second component, and determine the bonding alignment position of the first and second components, thereby improving the bonding accuracy between the second component 40 and the first component 30.

In some embodiments, in the bonding apparatus provided in the embodiments of the present disclosure, the reference assembly 20 may further be arranged, and configured to correct the relative position between the first component 30 and the second component 40 according to the correction information. In this way, by performing only a single recognition of the alignment mark (such as the first alignment mark B1, the second alignment mark B2) on the first component 30 and performing only a single recognition of the reference mark on the reference element 23 in the reference assembly 20, it may be possible to determine both the calibrated coordinate system and the fixed coordinate in the calibrated coordinate system, such that the coordinate relationship of the alignment mark (such as the third alignment mark T1, the fourth alignment mark T2) on the second component 40 may further be determined in the calibrated coordinate system. Therefore, it may be possible to determine the correction information and correct the relative position between the first component 30 and the second component 40. Therefore, the bonding apparatus provided by the embodiments of the present disclosure may complete the alignment and bonding of the second component 40 and the first component 30 without requiring two cameras to simultaneously recognize the alignment mark on the first component 30 and the alignment mark on the second component 40 in a same field-of-view. At the same time, it is not necessary to perform multiple alignments for each second component 40, thereby effectively reducing the time consumption and improving the bonding efficiency and yield.

In some embodiments, since in the bonding apparatus provided by the embodiments of the present disclosure, since two image acquisition members, i.e., the first image acquisition member 21 and second image acquisition member 22, and the reference member 23 of the reference assembly 20 may be used to simultaneously recognize the reference mark on the reference member 23, a distribution of the alignment mark on the first component 30 and the alignment mark on the second component 40 is not limited. In this way, it may be possible to effectively reduce the influence of the field-of-view of the camera on the alignment mark on the first component 30 and the alignment mark on the second component 40.

In some embodiments, in the bonding apparatus provided by the embodiments of the present disclosure, the first macro-driving member/the first micro-driving member, the second macro-driving member/the second micro-driving member, the second driving member 133, and the rotation driving member 134 of the movable pick-up platform 13 may cooperate with the grating assembly 24, such that the motion closed-loop may be formed. In this way, it may be possible to enable the movable pick-up platform 13 to implement the positioning with sub-micron accuracy, thereby effectively improving the bonding accuracy.

It may be understood that the bonding apparatus provided in the embodiments of the present disclosure may be applied not only to a chip-to-wafer (C2W) bonding technology. That is, in the bonding apparatus described in the above embodiments, the high-precision movement platform and the motion closed-loop may be formed by the cooperation of the gantry 11, the base frame 12, the movable pick-up platform 13, and the laser interferometer assembly 24 in the machine base 10, such that a to-be-bonded chip may be moved to the predetermined surface position of the wafer and may be bonded to the predetermined surface position of a to-be-bonded wafer. In some embodiments, the bonding apparatus provided in the embodiments of the present disclosure may further be applied to a wafer-to-wafer (W2W) bonding technology. In the bonding apparatus described in the above embodiments, the high-precision movement platform and the motion closed-loop may be formed by the cooperation of the gantry 11, the base frame 12, the movable pick-up platform 13, and the laser interferometer assembly 24 in the machine base 10, such that a to-be-bonded first wafer may be moved to the predetermined surface position of the wafer and may be bonded to a predetermined surface position of a to-be-bonded second wafer. The working principle and the technical effect to be achieved, which is applied to the W2W bonding technology, may be basically the same as those applied to the C2W bonding technology, the specific content of which may refer to the relevant descriptions in the above embodiments. Similarly, the bonding apparatus provided in the embodiments of the present disclosure may further be applied to a chip-to-chip (C2C) bonding technology, and the working principle and the technical effect to be achieved, which is applied to the C2C bonding technology, may also be basically the same as those applied to the C2W bonding technology, the specific content of which may refer to the relevant descriptions in the above embodiments.

Based on the above-mentioned bonding apparatus, a method for bonding the second component 40 to the first component 30 by using the above-mentioned bonding apparatus may be described as follows. FIG. 10 is a schematic flowchart of a bonding method according to some embodiments of the present disclosure. The operation of the bonding method provided by the embodiments may be described in detail in combination with FIGS. 2-10.

In some embodiments, as shown in FIG. 10, the bonding method may be applied to the bonding apparatus 100 according to any one of the above-mentioned embodiments. The bonding method may include the following operations.

In an operation S10, a first alignment mark and a second alignment mark on a to-be-bonded first component may be read.

In some embodiments, as shown in FIG. 3, the first image acquisition member 21 may be driven to move with the first driving member 131 to the position below the first chuck 14 carrying the first component 30. That is, the field-of-view of the first image acquisition member 21 is positioned within an area where the first component 30 is located. At this time, the first image acquisition member 21 may read the first alignment mark B1 and the second alignment mark B2 on the first component 30. In some embodiments, based on the read first alignment mark B1 and the second alignment mark B2, the second image acquisition member 22 may cooperate with the reference member 23 and the first image acquisition member 21 to define the calibrated coordinate system, as shown in FIG. 4.

In an operation S20, a third alignment mark and a fourth alignment mark on a to-be-bonded second component may be read.

In some embodiments, as shown in FIG. 5, the movable pick-up platform 13 may be controlled to pick up the second component 40 through the bonding head 135, and the picked-up second component 40 may be moved to the position below the second image acquisition member 22 until the field-of-view of the second image acquisition member 22 is positioned above the third alignment mark T1 and the fourth alignment mark T2 on the second component 40, i.e., a position may correspond to a direction of an end of the bonding head 135 facing the second image acquisition member 22. Therefore, the second image acquisition member 22 may read the third alignment mark T1 and the fourth alignment mark T2 on the second component 40. In this way, the third alignment mark T1 and the fourth alignment mark T2 on the second component 40 picked up by the bonding head 135 may be read by the second image acquisition member 22.

In an operation S30, a calibrated coordinate system may be determined based on the first alignment mark and the second alignment mark or based on the third alignment mark and the fourth alignment mark.

In an operation S40, a fixed coordinate in the calibrated coordinate system may be determined.

In some embodiments, as shown in FIG. 3, the operation S40 may include the following implementation process. The first image acquisition member 21 may be driven to move with the first driving member 131. For example, the first image acquisition member 21 may be driven to move to the position above the second image acquisition member 22 until a connecting line between a center point of the first image acquisition member 21 and a center point of the second image acquisition member 22 is approximately perpendicular to a plane at which the first chuck 14 is located, i.e., the center point of the first image acquisition member 21 and the center point of the second image acquisition member 22 may be aligned with each other in a direction approximately parallel to the third direction Z. In some embodiments, the reference member 23 is moved to the position below the second image acquisition member 22, and is moved to be located between the first image acquisition member 21 and the second image acquisition member 22. At this time, a connecting line between the center point of the first image acquisition member 21, a center point of the reference member 23, and the center point of the second image acquisition member 22 may be approximately perpendicular to the plane at which the first chuck 14 is located. In this way, the reference mark 231 may be simultaneously recognized by the first image acquisition member 21 and the second image acquisition member 22, such that it may be possible to determine the fixed coordinate in the calibrated coordinate system.

In this way, the calibrated coordinate system and the fixed coordinate shown in FIG. 4 may be obtained through the operations S10 to S40.

In an operation S50, first-direction coordinate information and second-direction coordinate information may be determined based on the first alignment mark, the second alignment mark, the third alignment mark, the fourth alignment mark alignment mark, and the fixed coordinate.

In some embodiments, the operation S50 may include: controlling the grating assembly 24 to generate the first-direction coordinate information related to the coordinate relationship of the first alignment mark B1, the second alignment mark B2, the third alignment mark T1, and the fourth alignment mark T2 along the first direction Y in the calibrated coordinate system; and controlling the grating assembly 24 to generate the second-direction coordinate information related to the coordinate relationship of the first alignment mark B1, the second alignment mark B2, the third alignment mark T1, and the fourth alignment mark T2 along the second direction X in the calibrated coordinate system.

In some embodiments, the operation of generating the first-direction coordinate information related to the coordinate relationship along the first direction Y includes: determining, by the first grating unit 241, displacement information of the movable pick-up platform along the first direction; and generating coordinate information of the first alignment mark, the second alignment mark, the third alignment mark, and the fourth alignment mark along the first direction in the calibrated coordinate system, based on the displacement information along the first direction. In some embodiments, when the first micro-driving member finely moves the second driving member 133 and the rotation driving member 134 in the horizontal plane along the first direction Y, resulting in a displacement change along the first direction Y, i.e., which may enable the second driving member 133 and the rotation driving member 134 undergo the displacement change along the first direction Y, the first grating unit 241 of the grating assembly 24 may be capable of measuring the displacement change of the second driving member 133 and the rotation driving member 134 along the first direction Y due to a case that the movable pick-up platform 13 may be capable of freely moving within the plane where the base frame 12 is disposed and the grating assembly 24 is disposed on the base frame 12. In some embodiments, the computer system 243 may be configured to convert the displacement change along the first direction Y into the coordinate information along the first direction Y, so as to generate the first-direction coordinate information related to the coordinate relationship of the first alignment mark B1, the second alignment mark B2, the third alignment mark T1, and the fourth alignment mark T2 along the first direction Y.

In some embodiments, as shown in FIG. 6, the first-direction coordinate information related to the coordinate relationship of the first alignment mark B1, the second alignment mark B2, the third alignment mark T1, and the fourth alignment mark T2 along the first direction Y may be expressed in the following manner. That is, in the calibrated coordinate system, the first alignment mark B1, the second alignment mark B2, the third alignment mark T1, and the fourth alignment mark T2 may be assumed to be ordinate values on the Y-axis, respectively. For example, the first alignment mark B1, the second alignment mark B2, the third alignment mark T1, and the fourth alignment mark T2 may be respectively marked as B1 ( . . . , y_{B1}), B2 ( . . . , y_{B2}), T1 ( . . . , y_{T1}), and T2 ( . . . , y_{T2}), which may be the coordinate information along the first direction Y.

Similarly, the operation of generating the second-direction coordinate information related to the coordinate relationship along the second direction X includes: determining, by the second grating unit 242, displacement information of the movable pick-up platform along the second direction; and generating coordinate information of the first alignment mark, the second alignment mark, the third alignment mark, and the fourth alignment mark along the second direction in the calibrated coordinate system, based on the displacement information along the second direction. In some embodiments, when the second micro-driving member finely moves the second driving member 133 and the rotation driving member 134 in the horizontal plane along the second direction X, resulting in a displacement change along the second direction X, i.e., which may enable the second driving member 133 and the rotation driving member 134 undergo the displacement change along the second direction X, the first grating unit 241 of the grating assembly 24 may be capable of measuring the displacement change of the second driving member 133 and the rotation driving member 134 along the second direction X due to a case that the movable pick-up platform 13 may be capable of freely moving within the plane where the base frame 12 is disposed and the grating assembly 24 is disposed on the base frame 12. In some embodiments, the computer system 243 may be configured to convert the displacement change along the second direction X into the coordinate information along the second direction X, so as to generate the second-direction coordinate information related to the coordinate relationship of the first alignment mark B1, the second alignment mark B2, the third alignment mark T1, and the fourth alignment mark T2 along the second direction X. That is, when the displacement of the first driving member 131 of the movable pick-up platform 13 along the second direction X may be measured by the second grating unit 242 of the grating assembly 24, the coordinate relationship of the first alignment mark B1, the second alignment mark B2, the third alignment mark T1, and the fourth alignment mark T2 along the second direction X may be determined. In addition, the system connection line of the grating assembly 24 and the computer system 243 may cooperate to generate the second-direction coordinate information related to coordinate relationship of the first alignment mark B1, the second alignment mark B2, the third alignment mark T1, and the fourth alignment mark T2 along the second direction X.

In some embodiments, as shown in FIG. 6, the second-direction coordinate information related to the coordinate relationship of the first alignment mark B1, the second alignment mark B2, the third alignment mark T1, and the fourth alignment mark T2 along the second direction X may be expressed in the following manner. That is, in the calibrated coordinate system, the first alignment mark B1, the second alignment mark B2, the third alignment mark T1, and the fourth alignment mark T2 may be assumed to be abscissa values on the X-axis, respectively. For example, the first alignment mark B1, the second alignment mark B2, the third alignment mark T1, and the fourth alignment mark T2 may be respectively marked as B1 (x_{B1}, . . . ), B2 (x_{B2}, . . . ), T1 (x_{T1}, . . . ), and T2 (x_{T2}, . . . ), which may be the coordinate information along the second direction X.

In this way, the coordinate information in the calibrated coordinate system shown in FIG. 7 may be obtained through the operation S50. In some embodiments, the coordinate information may be marked as B1 (x_{B1}, y_{B1}), B2 (x_{B2}, y_{B2}), T1 (x_{T1}, y_{T1}), and T2 (x_{T2}, y_{T2}) in the calibrated coordinate system.

It may be understood that there is no sequence of precedence among the above-mentioned operations S20 to S50 of the bonding method in the embodiments of the present disclosure, as long as the coordinate information in the calibrated coordinate system shown in FIG. 7, such as B1 (x_{B1}, y_{B1}), B2 (x_{B2}, y_{B2}), T1 (x_{T1}, y_{T1}), and T2 (x_{T2}, y_{T2}) in the calibrated coordinate system, may be obtained through the above-mentioned operations. For example, after determining the fixed coordinate in the calibrated coordinate system through the operation S40, the reference member 23 may be moved away (for example, the reference member 23 may be moved out of the maximum field-of-view of the first/second image acquisition members), and the operation S20 may be performed.

In an operation S60, a bonding alignment position of the first component and the second component may be determined based on the first-direction coordinate information and the second-direction coordinate information.

In some embodiments, the operation S60 may include: determining an angular deviation based on coordinate information of the first alignment mark, the second alignment mark, the third alignment mark, and the fourth alignment mark along a first direction and coordinate information of the first alignment mark, the second alignment mark, the third alignment mark, and the fourth alignment mark along a second direction; determining correction information based on the first-direction coordinate information, the second-direction coordinate information, and the angular deviation; correcting a relative position between the first component and the second component based on the correction information; and determining the bonding alignment position of the first component and the second component based on the corrected relative position.

In some embodiments, based on the coordinate information, such as B1 (x_{B1}, y_{B1}), B2 (x_{B2}, y_{B2}), T1 (x_{T1}, y_{T1}), and T2 (x_{T2}, y_{T2}), determined in the operation S50, the first angle α1 may be determined through the coordinate information of B1 (x_{B1}, y_{B1}) and B2 (x_{B2}, y_{B2}), and the second angle α2 may be determined through the coordinate information of T1 (x_{T1}, y_{T1}) and T2 (x_{T2}, y_{T2}), so as to determine the angular deviation Δα between the first component 30 and the second component 40 in the calibrated coordinate system, as shown in FIG. 7. In the calibrated coordinate system, the first connecting line between the third alignment mark T1 and the fourth alignment mark T2 on the second component 40 may be assumed to be L1, i.e., a connecting line between B1 and B2. The first angle between the L1 and the X-axis direction in the calibrated coordinate system may be assumed to be α1. The second connecting line between the first alignment mark B1 and the second alignment mark B2 on the first component 30 may be assumed to be L2, i.e., a connecting line between T1 and T2. The second angle between the L2 and the X-axis direction in the calibrated coordinate system may be assumed to be α2. The angular deviation Δα between the first component 30 and the second component 40 in the calibrated coordinate system is the absolute value of the difference between the first angle α1 and the second angle α2.

In some embodiments, the operation of determining the bonding alignment position of the first component and the second component based on the corrected relative position may include: rotating the bonding head 135 to correct the angular deviation to be within a predetermined threshold based on the angular deviation; reading first-direction verification coordinate information and second-direction verification coordinate information of the second component 40; and verifying a correction result of the angular deviation based on the read first-direction verification coordinate information and the read second-direction verification coordinate information of the second component 40. In some embodiments, when the angular deviation Δα is greater than a predetermined threshold, the grating assembly 24 cooperates with the first macro-driving/micro-driving member, the second macro-driving/micro-driving member, the second driving member 133, and the rotation driving member 134 to implement the positioning with sub-micron accuracy along the first direction Y, the second direction X, and the third direction Z and implement positioning with micro-radian-level accuracy for the bonding head 135. In this way, the movable pick-up platform 13 may form a high-precision movement platform, such that the bonding head 135 may be driven to adjust the position of the second component 40 until the angular deviation Δα is less than or equal to the predetermined threshold. An angular deviation of the predetermined threshold may be 0°, 0.5°, or 1°. A specific value of the angular deviation of the predetermined threshold may be set according to specific design requirements, which is not limited herein. In some embodiments, the angular deviation of the predetermined threshold Δα=0°, i.e., α1′=α2. α1′ represents a third angle between a third connecting line L1′ and the X-axis direction in the calibrated coordinate system after the position of the second component 40 is adjusted, where the third connecting line L1′ is a connecting line between the third alignment mark T1 and the fourth alignment mark T2.

In some embodiments, as shown in FIG. 7, in the calibrated coordinate system, the coordinate information of the position of the second component 40 after being adjusted by the bonding head 135 may be described as follows. The coordinate information corresponding to the coordinate relationship of the third alignment mark T1 and the fourth alignment mark T2 along the first direction Y and the coordinate relationship of the third alignment mark T1 and the fourth alignment mark T2 along the second direction X may be described that in the calibrated coordinate system, a position of the third alignment mark T1 may be adjusted to (x′_{T1}, y′_{T1}), and a position of the third alignment mark T2 may be adjusted to T2 (x′_{T1}, y′_{T2}). Thus, α1′ may be calculated through the adjusted coordinate information T1 (x′_{T1}, y′_{T1}) and T2 (x′_{T2}, y′_{T2}).

In an operation S70, the second component may be bonded to a predetermined surface position of the first component. That is, the second component may be bonded to the predetermined surface position of the first component by the bonding head.

In some embodiments, when α1′ is adjusted to meet the condition that the angular deviation Δα=0, i.e., α1′=α2, which indicates that the relative position between the first component 30 and the second component 40 reaches the predetermined threshold. At the same time, the coordinate information of the third alignment mark T1 and the fourth alignment mark T2 in the calibrated coordinate system may be illustrated in FIG. 9. In some embodiments, the second driving member of the movable pick-up platform may move the second component to the predetermined surface position of the first component, and the second component may be bonded to the predetermined surface position of the first component, as shown in FIG. 8.

The bonding method provided in the embodiments of the present disclosure may be applied to the above-mentioned bonding apparatus, and therefore the bonding method may also have the same technical effect, which will not be repeated herein.

The above is only some embodiments of the present disclosure, and is not intended to limit the scope of the present disclosure. Any equivalent structure or equivalent process transformation using the contents and the accompanying drawings of the present disclosure, or any direct or indirect application in other related technical fields, is included in the scope of the present disclosure.

1. A bonding apparatus, comprising:
a machine base, comprising a movable pick-up platform; and
a grating assembly, configured to determine displacement information of the movable pick-up platform along a first direction and displacement information of the movable pick-up platform along a second direction;
wherein based on the displacement information along the first direction and the displacement information along the second direction, the grating assembly is further configured to determine coordinate information of the movable pick-up platform.

2. The bonding apparatus according to claim 1, wherein the machine base further comprises a base frame and a gantry arranged on the base frame;
the grating assembly is disposed on the base frame, the grating assembly is further configured to measure a displacement change of the movable pick-up platform along the first direction and a displacement change of the movable pick-up platform along the second direction, and displacement information of the movable pick-up platform along the first direction and displacement information of the movable pick-up platform along the second direction are determined respectively.

3. The bonding apparatus according to claim 2, further comprising:
a first chuck, configured to carry a to-be-bonded first component;
a first image acquisition member, disposed at a side of the movable pick-up platform away from the base frame and having a first viewing angle, and configured to read a first alignment mark and a second alignment mark on the to-be-bonded first component; and
a second image acquisition member, disposed at a side of the first chuck and having a second viewing angle, and configured to read a third alignment mark and a fourth alignment mark on a to-be-bonded second component picked up by the movable pick-up platform.

4. The bonding apparatus according to claim 3, wherein in a case where a field-of-view of the first image acquisition member is within an area where the to-be-bonded first component is located, the first image acquisition member is configured to read the first alignment mark and the second alignment mark on the to-be-bonded first component; and
in a case where the to-be-bonded second component picked up by the movable pick-up platform is moved into a field-of-view of the second image acquisition member, the second image acquisition member is configured to read the third alignment mark and the fourth alignment mark on the to-be-bonded second component.

5. The bonding apparatus according to claim 3, further comprising a reference assembly disposed on the machine base;
wherein the reference assembly is arranged with a reference mark, and in a case where the reference assembly is disposed at a same position, the first image acquisition member and the second image acquisition member are configured to obtain different coordinate information by recognizing the reference mark, and a fixed coordinate in a calibrated coordinate system is determined.

6. The bonding apparatus according to claim 5, wherein the reference assembly is capable of being driven to move freely between a top plate of the gantry and the second image acquisition member, and a free movement range of the reference assembly is not less than an intersection of a maximum field-of-view of the first image acquisition member and a maximum field-of-view of the second image acquisition member.

7. The bonding apparatus according to claim 5, wherein the reference assembly comprises the reference member, and the reference member comprises one of a transparent component, a translucent component, and a structural component with a through-hole.

8. The bonding apparatus according to claim 5, wherein the grating assembly further comprises: a computer system connected to the grating assembly;
wherein in a case where the first alignment mark and the second alignment mark are read, or in a case where the third alignment mark and the fourth alignment mark are read, the computer system is configured to define the calibration coordinate system;
in response to the determined fixed coordinates, the computer system is configured to generate coordinate information along the first direction and coordinate information along the second direction of the first alignment mark, the second alignment mark, the third alignment mark, and the fourth alignment mark in the calibration coordinate system; and
in response to the generated coordinate information along the first direction and the generated coordinate information along the second direction, the computer system is further configured to determine an angular deviation between a predetermined surface position of the to-be-bonded first component and a position of the to-be-bonded second component, and the grating assembly cooperates with the movable pick-up platform to adjust the position of the to-be-bonded second component, such that the to-be-bonded second component is bonded to the predetermined surface position of the to-be-bonded first component.

9. The bonding apparatus according to claim 3, wherein the second image acquisition member is arranged with a reference mark, and the first image acquisition member is configured to determine the fixed coordinate in the calibrated coordinate system by reading the reference mark.

10. The bonding apparatus according to claim 1, wherein the movable pick-up platform comprises a first driving member, a second driving member, a rotation driving member, and a bonding head sequentially stacked on a side of a base frame facing a top plate of a gantry;
the bonding head is connected to the rotation driving member, and an end of the bonding head faces the top plate;
the first driving member comprises:
a first macro-driving member, disposed at a side of the base frame facing the top plate and configured to move the bonding head in a horizontal plane along the first direction; and
a first micro-driving member, disposed at the side of the base frame facing the top plate and configured to finely move the bonding head in the horizontal plane along the first direction; and
the second driving member comprises:
a second macro-driving member, disposed at the side of the base frame facing the top plate and configured to move the bonding head in the horizontal plane along the second direction; and
a second micro-driving member, disposed at the side of the base frame facing the top plate and configured to finely move the bonding head in the horizontal plane along the second direction.

11. The bonding apparatus according to claim 10, further comprising a second chuck, configured to hold a to-be-bonded second component;
wherein the machine base further comprises a pickup head, and the pickup head is capable of being driven to move freely in a range of the machine base, and configured to pick up the to-be-bonded second component from the second chuck and transfer the to-be-bonded second component to the bonding head.

12. The bonding apparatus according to claim 1, wherein the grating assembly comprises a first grating unit and a second grating unit;
the first grating unit comprises:
a first grating scale;
a first telescoping member, wherein one end of the first telescoping member is connected to the first grating scale, the other end of the first telescoping member is connected to the movable pick-up platform, and the first telescoping member is configured to synchronously move with the movable pick-up platform along the first direction and telescopically retract with the movable pick-up platform 13 along the second direction; and
the second grating unit comprises:
a second grating scale;
a second telescoping member, wherein one end of the second telescoping member is connected to the second grating scale, the other end of the second telescoping member is connected to the movable pick-up platform, and the second telescoping member is configured to synchronously move with the movable pick-up platform along the second direction and telescopically retract along the first direction.

13. The bonding apparatus according to claim 12, wherein the first grating unit further comprises a first sensor located on the first grating scale, connected to the first telescoping member, and configured to measure a displacement generated along the first direction; and
the second grating unit further comprises a second sensor located on the second grating scale, connected to the second telescoping member, and configured to measure a displacement generated along the second direction.

14. The bonding apparatus according to claim 1, wherein the grating assembly comprises:
a first grating unit, parallel to the first direction and arranged on the machine base; and
a second grating unit, parallel to the second direction and arranged on the machine base;
wherein the first grating scale is configured to synchronously move with the movable pick-up platform along the first direction, and/or the second grating scale is configured to synchronously move with the movable pick-up platform along the second direction.

15. The bonding apparatus according to claim 14, wherein the first grating unit comprises a first sensor, disposed on the first grating scale and configured to synchronously move with the movable pick-up platform along the first direction and measure a displacement along the first direction; and
the second grating unit comprises a second sensor, disposed on the second grating scale, and configured to synchronously move with the movable pick-up platform along the second direction and measure a displacement along the second direction.

16. A bonding method, comprising:
reading a first alignment mark and a second alignment mark on a to-be-bonded first component;
reading a third alignment mark and a fourth alignment mark on a to-be-bonded second component;
determining a calibrated coordinate system based on the first alignment mark and the second alignment mark or based on the third alignment mark and the fourth alignment mark;
determining a fixed coordinate in the calibrated coordinate system;
determining first-direction coordinate information and second-direction coordinate information based on the first alignment mark, the second alignment mark, the third alignment mark, the fourth alignment mark, and the fixed coordinate;
determining a bonding alignment position of the to-be-bonded first component and the to-be-bonded second component based on the first-direction coordinate information and the second-direction coordinate information; and
bonding the to-be-bonded second component to a predetermined surface position of the to-be-bonded first component.

17. The bonding method according to claim 16, wherein the determining a bonding alignment position of the to-be-bonded first component and the to-be-bonded second component based on the first-direction coordinate information and the second-direction coordinate information, comprises:
determining an angular deviation based on coordinate information of the first alignment mark, the second alignment mark, the third alignment mark, and the fourth alignment mark along a first direction and coordinate information of the first alignment mark, the second alignment mark, the third alignment mark, and the fourth alignment mark along a second direction;
determining correction information based on the first-direction coordinate information, the second-direction coordinate information, and the angular deviation;
correcting a relative position between the to-be-bonded first component and the to-be-bonded second component based on the angular deviation; and
determining the bonding alignment position of the to-be-bonded first component and the to-be-bonded second component based on the corrected relative position.

18. The bonding method according to claim 17, wherein the correcting a relative position between the to-be-bonded first component and the to-be-bonded second component based on the angular deviation, comprises:
rotating a bonding head to correct the angular deviation to be within a predetermined threshold based on the angular deviation;
reading first-direction verification coordinate information and second-direction verification coordinate information of the to-be-bonded second component; and
verifying a correction result of the angular deviation based on the read first-direction verification coordinate information and the read second-direction verification coordinate information of the to-be-bonded second component.

19. The bonding method according to claim 16, wherein the determining a fixed coordinate in the calibrated coordinate system, comprises:
obtaining, by a first image acquisition member and a second image acquisition member, different coordinate information by recognizing a reference mark, and determining the fixed coordinate by reading the different coordinate information, in a case where a reference assembly is disposed at a same position.

20. The bonding method according to claim 16, wherein the determining first-direction coordinate information and second-direction coordinate information based on the first alignment mark, the second alignment mark, the third alignment mark, the fourth alignment mark, and the fixed coordinate, comprises:
controlling the grating assembly to measure a displacement of the first driving member along the first direction and a displacement of the first driving member along the second direction, and determining displacement information along the first direction and displacement information along the second direction of the first alignment mark, the second alignment mark, the third alignment mark, and the fourth alignment mark, and
controlling the computer system to convert the displacement information along the first direction and the displacement information along the second direction into coordinate information along the first direction and coordinate information along the second direction, respectively.
